(19) United States
(12) Patent Application Publication
(10) Pub. No.: US 2013/0171798 A1
(43) Pub. Date: Jul. 4, 2013

(54) METHOD OF MANUFACTURING PHASE-CHANGE RANDOM ACCESS MEMORY DEVICE

(71) Applicants: Seung Beom BAEK, Icheon-si (KR); Hyung Suk Lee, Icheon-si (KR)

(72) Inventors: Seung Beom BAEK, Icheon-si (KR); Hyung Suk Lee, Icheon-si (KR)

(21) Appl. No.: 13/482,190

(22) Filed: May 29, 2012

(30) Foreign Application Priority Data
Dec. 30, 2011 (KR) 10-2011-0146913

(51) Int. Cl. H01L 21/02

(52) U.S. Cl. 438/381; 257/E21.003

(57) ABSTRACT

A method of manufacturing a phase-change random access memory device. The method includes forming a word line on a semiconductor substrate, forming a switching element material and a hard mask material on the word line, etching the switching element material and the hard mask material to form a hole exposing the word line, forming an insulating material on a sidewall and a bottom of the hole, removing the hard mask material; and forming a heater material on the switching element material. The hard mask material has different etch selectivity from the insulating material.

### CROSS-REFERENCES TO RELATED APPLICATION

The present application claims priority under 35 U.S.C. 119(a) to Korean application number 10-2011-0146913, filed on Dec. 30, 2011, in the Korean Patent Office, which is incorporated by reference in its entirety as if set forth in full.

### BACKGROUND OF THE INVENTION

1. Technical Field

Exemplary embodiments of the present invention relate to a nonvolatile memory device, and more particularly, to a method of manufacturing a phase-change random access memory (PCRAM) device.

2. Related Art

With the demands on lower power consumption of memory devices, memory devices having non-volatility and non-refreshment properties have been developed. A PCRAM device, as one of such memory devices, applies a pulse to a phase-change layer which is a chalcogenide compound to store data using a difference between a resistance in an amorphous state and a resistance in a crystalline state.

FIGS. 1A to 1D are views illustrating a method of a manufacturing a typical PCRAM device.

As shown in FIG. 1A, a word line region 20 is formed on a semiconductor substrate 10, and a barrier metal material 30 and a ploysilicon material 40, which are materials for forming a shottky diode, an ohmic contact material 50, and a nitride material 60 serving as a hard mask are sequentially stacked on the word line region 20.

As shown in FIG. 1B, the barrier metal material 30, the polysilicon material 40, the ohmic contact material 50, and the nitride material 60 are etched to expose the word line region 20, thereby forming a hole H. A nitride material layer 70 for a diode spacer which serves to protect a diode is formed along a surface of the hole H.

As shown in FIG. 1C, an oxide material 80 serving as an insulating layer is gap-filled within the hole H and as shown in FIG. 1D, the nitride material 60 is etched.

However, when the nitride material 60 serving as a hard mask is etched in the PCRAM device, the nitride material 70 for a diode spacer is also etched. It is because the nitride material 60 serving as a hard mask has the same material as the nitride material 70 for a diode spacer.

Thus, in the PCRAM device, oxidation between the diode and a lower electrode to be formed may be caused by the removal of the nitride material for a diode spacer and uniformity of hole patterns may be degraded.

### SUMMARY

Exemplary embodiments of the present invention are provided to a method of manufacturing a PCRAM device capable of preventing oxidation from being caused between a diode and a lower electrode and improving pattern uniformity thereof by modifying a material serving as a hard mask.

According to an exemplary embodiment, a method of manufacturing a PCRAM device includes: forming a word line on a semiconductor substrate; forming a switching element material and a hard mask material on the word line; etching the switching element material and the hard mask material to form a hole exposing the word line; forming an insulating material on a sidewall and a bottom of the hole; removing the hard mask material; and forming a heater material on the switching element material, wherein the hard mask material has different etch selectivity from the insulating material.

According to another exemplary embodiment, a method of manufacturing a PCRAM device includes: forming a word line on a semiconductor substrate; forming a switching element material on the word line; forming a hard mask on the switching element material; etching the switching element material using the hard mask as an etching barrier to form a switching element; and forming a heater material on the switching element, wherein the hard mask includes silicon germanium (SiGe).

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1A to 1D are views illustrating a method of manufacturing a typical PCRAM device; and

FIGS. 2A to 2E are views illustrating a method of manufacturing a PCRAM device according to an exemplary embodiment of the present invention.

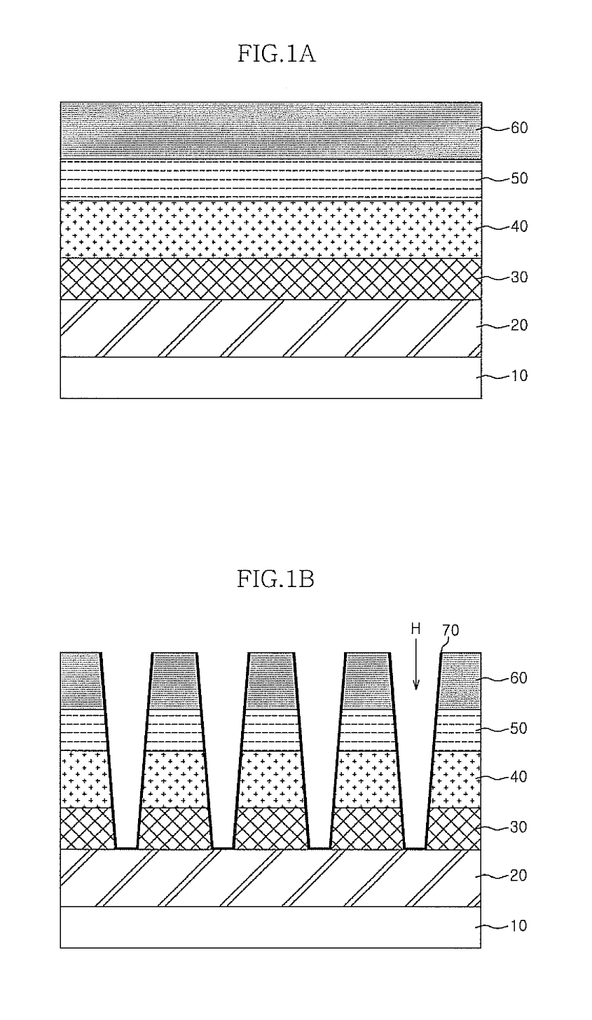

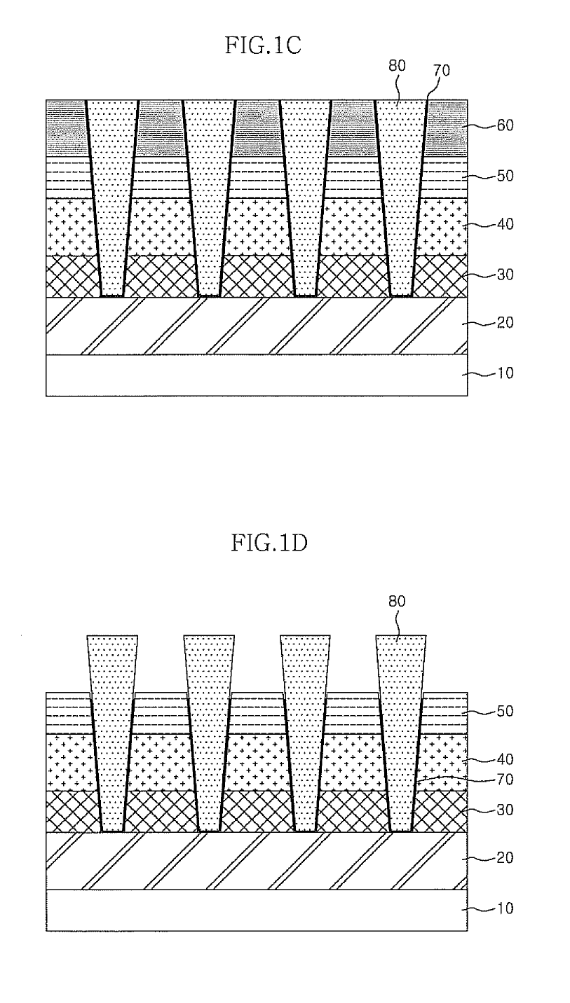

### DESCRIPTION OF EXEMPLARY EMBODIMENT

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result of, for example, manufacturing techniques and/or tolerances are to be expected. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

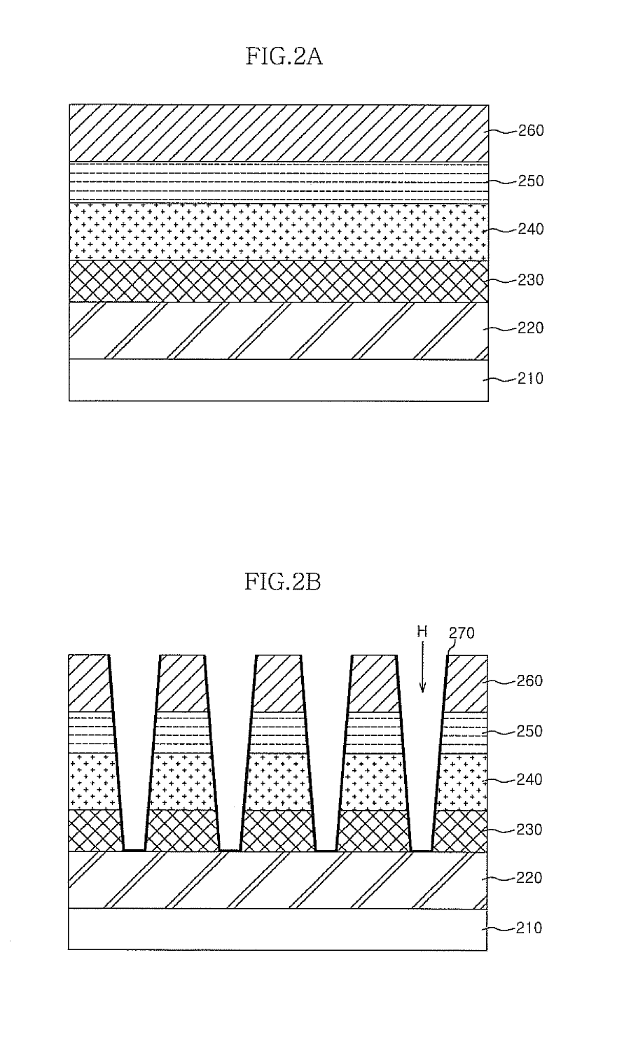

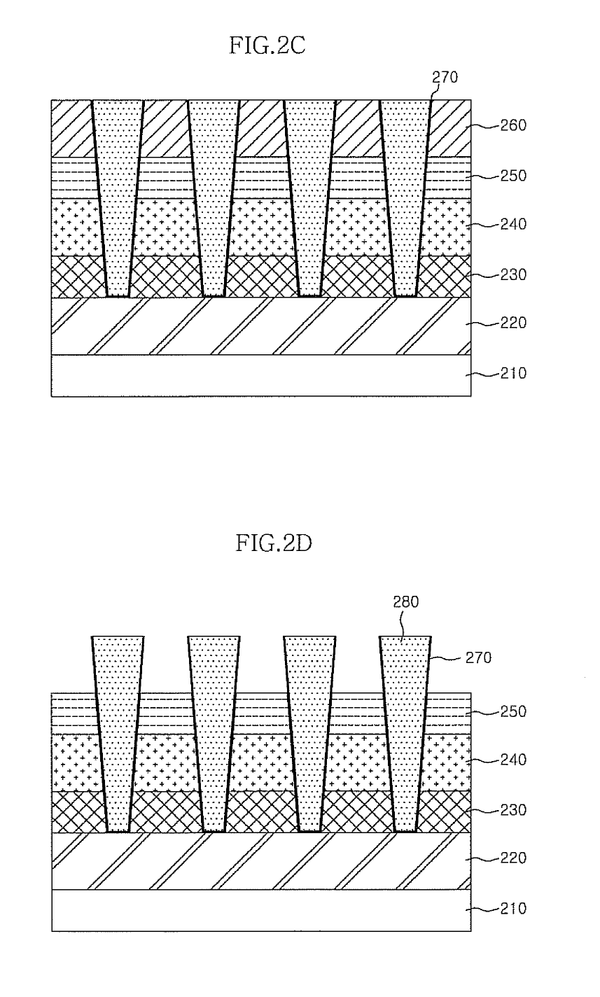

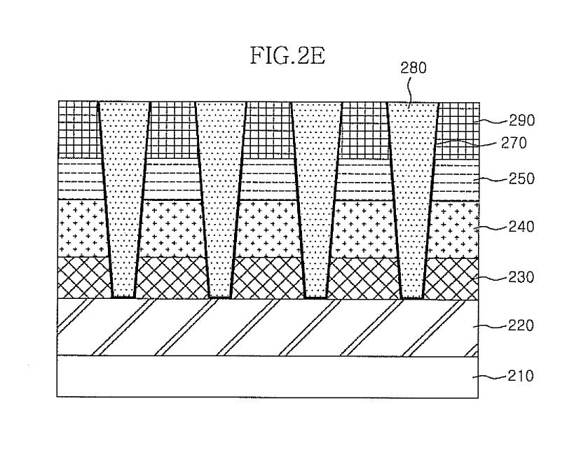

FIGS. 2A to 2E are views illustrating a method of manufacturing a PCRAM device according to an exemplary embodiment.

As shown in FIG. 2A, the method of manufacturing a PCRAM device includes forming a word line 220 including a metal layer or a metal nitride layer on a semiconductor substrate 210. A barrier metal material 230 and a polysilicon material 240 which are materials for forming a switching element, an ohmic contact material 250 serving as an ohmic contact layer, and a SiGe material 260 serving as a hard mask are sequentially stacked on the word line 220. The SiGe material 260 is formed at a deposition temperature between 400° C. and 800° C.

As shown in FIG. 2B, the barrier metal material 230, the polysilicon material 240, the ohmic contact material 250, and the SiGe material 260 are etched in a pillar shape to expose the word line 220, thereby forming a hole H.

A nitride material 270 is deposited along an inner surface of the hole H. To deposit the nitride material 270 along the internal surface of the hole H is to prevent atoms doped when the switching element is formed from being diffused.

As shown in FIG. 2C, an oxide-based material 280 serving as an insulating layer is gap-filled within the hole H which has the nitride material 270 deposited on the inner surface thereof. At this time, a material serving as an insulating layer is not limited to the oxide-based material 280. The nitride-based material may be deposited as the material serving as an insulating layer. After the gap-filling process is performed, the oxide-based material 280 is planarized to expose the SiGe material 260 using a chemical mechanical polishing (CMP) method.

As shown in FIG. 2D, only the SiGe material 260 serving as a hard mask is selectively removed. At this time, only the SiGe material 260 is selectively removed using HF:H₂O₂:CH₃COOH or HNO₃:HF:CH₃COOH:DI H₂O (deionized water). Thus, since the SiGe material 260 is used as the hard mask material other than a nitride material in the conventional art, the nitride material 270, which is deposited along the inner surface of the hole after the switching element is formed, is prevented from being damaged so that pattern uniformity is improved and oxidation between the switching element and a lower electrode is prevented from being caused.

As shown in FIG. 2E, a heater material 290 for the lower electrode is formed on the ohmic contact material 250, that is, in an area from which the SiGe layer 260 is removed. At this time, the heater material 290 may include at least one selected from the group consisting of a metal, an alloy, a metal oxynitride, an oxide electrode, and a conductive compound. For example, the heater material 290 may include at least one selected from the group consisting of tungsten (W), titanium nitride (TiN), tantalum nitride (TaN), tungsten nitride (WN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium (Ti), molybdenum (Mo), tantalum (Ta), platinum (Pt), titanium silicide (TiSi), tantalum silicide (TaSi), titanium tungsten (TiW), titanium oxynitride (TiON), titanium aluminum oxynitride (TiAlON), tungsten oxynitride (WON), tantalum oxynitride (TaON), and iridium oxide (IrO2).

Then, although not shown in drawings, a phase-change material and an upper electrode material are sequentially stacked on the heater material 290 to form the PCRAM device according to the exemplary embodiment.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A method of manufacturing a phase-change random access memory device, comprising:
forming a word line on a semiconductor substrate;
forming a switching element material and a hard mask material on the word line;
etching the switching element material and the hard mask material to form a hole exposing the word line;
forming an insulating material on a sidewall and a bottom of the hole;
removing the hard mask material; and
forming a heater material on the switching element material,
wherein the hard mask material has different etch selectivity from the insulating material.

2. The method of claim 1, wherein the insulating material includes a nitride material.

3. The method of claim 1, wherein the hard mask material includes silicon germanium (SiGe).

4. The method of claim 3, wherein the forming of the hard mask material includes depositing the hard mask material on the switching element material at a temperature of 400° C. to 800° C.

5. The method of claim 3, wherein the removing of the hard mask material is performed using any one of HF:H₂O₂:CH₃COOH and HNO₃:HF:CH₃COOH:DI H₂O.

6. A method of manufacturing a phase-change random access device, comprising:
forming a word line on a semiconductor substrate;
forming a switching element material on the word line;
forming a hard mask on the switching element material;
etching the switching element material using the hard mask as an etching barrier to form a switching element and
forming a heater material on the switching element,
wherein the hard mask includes silicon germanium (SiGe).

7. The method of claim 6, wherein the forming of the hard mask includes:
depositing a hard mask material on the switching element material at a temperature of 400° C. to 800° C.; and
etching the hard mask material to form the hard mask.

8. The method of claim 6, further comprising, after the etching of the switching element material:
forming an insulating material having different etch selectivity from the hard mask on sidewalls of the switching element; and
removing the hard mask.

9. The method of claim 8, wherein the removing of the hard mask material is performed using any one of HF:H₂O₂:CH₃COOH and HNO₃:HF:CH₃COOH:DI H₂O.
